(19) United States
(12) Patent Application Publication
(10) Pub. No.: US 2024/0104397 A1
(43) Pub. Date: Mar. 28, 2024

(54) TIME-SERIES DATA PROCESSING METHOD AND PROCESSING DEVICE

(71) Applicant: TOYOTA JIDOSHA KABUSHIKI KAISHA, Toyota-shi (JP)

(72) Inventor: Kazuyuki SASAKI, Nisshin-shi (JP)

(73) Assignee: TOYOTA JIDOSHA KABUSHIKI KAISHA, Toyota-shi (JP)

(21) Appl. No.: 18/344,310

(22) Filed: Jun. 29, 2023

(30) Foreign Application Priority Data
Sep. 27, 2022 (JP) 2022-153454

(51) Int. Cl. G06N 5/02; G06N 5/04

(52) U.S. Cl. CPC G06N 5/02; G06N 5/04

(57) ABSTRACT

A processing device for time-series data for reducing a data amount of time-series data, comprising: a compression processing unit that performs predetermined compression processing on original data of quantized time-series data, reduces the data amount, and converts the data into data for storage in a form that can be stored in a storage unit, wherein the compression processing unit calculates a first statistical index related to the original data, excludes data corresponding to an exclusion condition from the original data as a missing value, performs compression processing on the original data excluding a missing value, generates compressed data in which the data amount is reduced, and stores the compressed data and the first statistical index in the storage unit as data for storage.

### CROSS-REFERENCE TO RELATED APPLICATION

This application claims priority to Japanese Patent Application No. 2022-153454 filed on Sep. 27, 2022, incorporated herein by reference in its entirety.

### BACKGROUND

### 1. Technical Field

The present disclosure relates to a technique for handling a large amount of data saved in a predetermined storage device or storage medium, and particularly, a technique of performing compression processing to reduce a data amount of time-series data that change continuously over time so as to use the data.

### 2. Description of Related Art

In recent years, practical application of a technique for efficiently performing processing of learning (or inference, recognition, determination, etc.) by utilizing advanced technologies such as artificial intelligence (AI) and information-communication technology (ICT) has been advanced. One of the learning methods executed by AI is machine learning. Machine learning learns by itself by using a large number of pieces of data given by a machine (computer), and optimizes output data with respect to input data based on the learning result (learned model). When a large amount of data such as that used as input data of the machine learning is saved in a predetermined storage device or storage medium, compression (or reduction in a data amount) processing of the data is usually performed. An disclosure relating to such a data compression processing is described in Japanese Unexamined Patent Application Publication No. 2012-10319 (JP 2012-10319 A).

JP 2012-10319 A describes a time-series data compressing method in which data is thinned out based on a threshold from numerical data sequences (time-series data). The time-series data compression method described in JP 2012-10319 A includes: a first step of performing initial setting of a threshold corresponding to a target compression rate by using a predetermined number of pieces of numerical data and a relationship of an expected value of a compression ratio corresponding to a specific compressing algorithm used for compressing and a threshold, a second step of compressing the numerical data by the compression algorithm by using a set threshold and calculating an actual compression rate of the numerical data for each predetermined number, a third step of determining whether the threshold needs to be reset based on the calculated actual compression rate and the target compression rate, and a fourth step of resetting the threshold corresponding to the target compression rate by using the recent predetermined number of pieces of numerical data and the relationship between the expected value and the threshold. Thus, in the time-series data compression method described in JP 2012-10319 A, the threshold serving as a reference when the time-series data is thinned out and compressed is automatically set so that a deviation from the target compression ratio becomes small.

Japanese Unexamined Patent Application Publication No. 2021-163162 (JP 2021-163162 A) describes a learning data processing device for the purpose of enhancing a quality of learning data. The learning data processing device described in JP 2021-163162 A includes a data processing unit that generates learning data used in a learning device that generates a learning model, based on time-series data including at least one type of measurement value. The data processing unit calculates at least one of a statistical value of a measurement value included in one or a plurality of predetermined periods among the time-series data, or at least one of an outlier determination upper limit value or an outlier determination lower limit value based on the statistical value, and excludes, from the time-series data, a measurement value that is at least one of the outlier determination upper limit value or the outlier determination lower limit value among the measurement values included in the predetermined period. Alternatively, a measurement value satisfying a predetermined condition among the measurement values included in the time-series data is excluded from the time-series data.

Further, Japanese Unexamined Patent Application Publication No. 2018-201787 (JP 2018-201787 A) describes a complementing device of time-series data of an instantaneous heartbeat for the purpose of enabling appropriate spectral analysis even if instantaneous heartbeat data includes a missing section caused by a measurement abnormality or the like. The complementing device of the time-series data of the instantaneous heartbeat described in JP 2018-201787 A calculates a complement value for a missing section of the time-series data of the instantaneous heartbeat having a missing section and a time of the missing section, and complements the calculated complement value to the missing section when the calculated time of the missing section is equal to or more than the complement time and the time obtained by subtracting the complement time from the missing section is equal to or more than a complement target time. Further, J P 2018-201787 A discloses that, for example, an average value of the instantaneous heartbeat in an analysis target section is used as the complement value described above.

### SUMMARY

A large amount of data such as those used in the above-described machine learning is saved in an auxiliary storage device or an external storage medium (storage media) of a server or a computer, for example. At this time, in order to avoid the storage capacity of the storage device or the storage medium from becoming strained, the data is saved in the storage device or the storage medium in a state in which the amount of data is reduced by performing a predetermined processing. For example, in the time-series data compression method described in Japanese Unexamined Patent Application Publication No. 2012-10319 (JP 2012-10319 A), data is irreversibly compressed by thinning out data under a predetermined condition, and the amount of data is reduced. In addition, for example, an irreversible data-compression format such as a Joint Photographic Experts Group (JPEG) is generally used.

In such a conventional data compression technique, it is not easy to determine whether individual data is required when data is compressed. For example, data related to image display data, character information, and the like is a relatively random or irregular collection of individual data, and when such data is compressed, it is not possible to easily determine the necessity or importance of each individual data. For this reason, for example, in the compression processing of the image display data by the above-described JPEG, the compression is set to have reduced accuracy on the whole and on the average, and an irreversible compression with isotropy is performed. On the other hand, for example, the change in a deterioration state, a remaining capacity, or a remaining life of a battery is a continuous change with time, and data on the deterioration state, the life, or the like of the battery is time-series data that changes continuously with time. The time-series data related to such a continuous event is not random or irregular data such as image display data and character information, and is basically continuous data with a certain tendency. Thus, in a case of compressing time-series data related to such continuous events, it is desirable to determine the necessity and importance of each individual data and compress the data, and it is not always appropriate to compress the data so as to reduce the accuracy on average with isotropy as described above.

As described above, there is still room for improvement in order to appropriately and effectively perform a compressing processing on time-series data (reduce an amount of data in the time-series data to be saved) when the time-series data that continuously changes with time is stored or saved and used.

The present disclosure has been made in view of the above technical problems, and an object of the present disclosure is to provide a time-series data processing method and a processing device that can take the necessity and importance of each individual data in a large amount of time-series data into consideration, while leaving important information, and appropriately and efficiently deleting and storing an amount of data.

In order to achieve the above object, the present disclosure is a time-series data processing method that reduces a data amount of a large amount of time-series data that varies continuously in time, the time-series data processing method includes:
a compression processing step that performs predetermined compression processing on original data of the time-series data that is quantized or discretized, and that reduces the data amount to make saved data in a form that is able be saved in a predetermined storage unit; and
a restoration processing step that performs restoration processing on the saved data, and that makes the saved data into study data in a form usable by predetermined calculation processing,
in which the compression processing step includes,
a step of calculating a first statistical index (or a basic statistical amount) regarding the original data,
a step of excluding, from the original data, data corresponding to a predetermined first condition for determining data having a low importance with respect to the calculating processing, as a missing value,
a step of performing the compression processing on the original data from which the missing value is excluded, and generating compressed data in which the data amount is reduced, and
a step of storing the compressed data and the first statistical index as the saved data in the storage unit, and
in which the restoration processing step includes,
a step of reading the saved data from the storage unit,
a step of generating restored data in which predetermined processing of restoring the saved data is performed on the saved data,
a step of calculating a second statistical index regarding the restored data,
a step of specifying a position corresponding to data applicable to a predetermined second condition as an interpolation target part, from a missing part of the restored data containing a trace in which the missing value is excluded, and
a step of calculating an interpolation value applied to the interpolation target part, compensating (interpolating) the interpolation target part with the interpolation value, and generating learning data in which the restored data is approximated to the original data, based on the first statistical index and the second statistical index.

In the time-series data processing method of the this disclosure, of the original data, the data corresponding to the first condition may be data that is equal to or lower than a lower limit threshold set as a lower limit value and equal to or higher than an upper limit threshold set as an upper limit value, and the data corresponding to the second condition may be data in which data before and after the missing value in a time-series direction of the original data is data within a predetermined range including the lower limit threshold or a predetermined range including the upper limit threshold, and the interpolation value may be extracted from a random number acquired based on a normal distribution function of the restored data, of the second statistical index.

In the time-series data processing method of the this disclosure, the calculation processing may be machine learning that performs learning based on a large amount of input data, and that performs estimation or determination based on a result of the learning, and the learning data may be the input data in the machine learning.

In the time-series data processing method of the this disclosure, the original data may be data regarding a power storage device mounted on a vehicle, and the machine learning may estimate a change over time of the power storage device.

In contrast, this disclosure is a time-series data processing device that reduces a data amount of a large amount of time-series data that varies continuously in time, the time-series data processing method may include
a compression processing unit that performs predetermined compression processing on original data of the time-series data that is quantized, and that reduces the data amount to make the original data into saved data in a form that is able be saved in a predetermined storage device or a storage medium,
in which the compression processing unit may
calculate a first statistical index regarding the original data,
exclude, from the original data, data corresponding to a predetermined excluding condition as a missing value,
perform the compression processing on the original data from which the missing value is excluded, and generate compressed data in which the data amount is reduced, and
save the compressed data and the first statistical index as the saved data in the storage device and the storage medium.

In addition, in the time-series data processing device of the this disclosure, of the original data, the data corresponding to the excluding condition may be data equal to or lower than a lower limit threshold set as a lower limit value and equal to or higher than an upper limit threshold set as an upper limit value.

Further, this disclosure is a time-series data processing device that reduces a data amount of a large amount of time-series data that varies continuously in time, the time-series data processing method may include
a restoring processing unit that performs restoring processing on saved data saved in a predetermined storage device or a storage medium and that makes the saved data into learning data in a form usable by predetermined calculation processing, the saved data being data in which predetermined compression processing is performed on original data from which data corresponding to a predetermined excluding condition is excluded as a missing value and the data amount is reduced, from the original data of the time-series data that is quantized,
in which the restoration processing unit may
read the saved data from the storage device or the storage medium,
generate restored data in which predetermined processing of restoring the saved data is performed on the saved data,
calculate a second statistical index regarding the restored data,
specify a position corresponding to data applicable to a predetermined interpolation condition as an interpolation target part, from a missing part of the restored data containing a trace in which the missing value is excluded, and
calculate an interpolation value applied to the interpolation target part, compensate (interpolate) the interpolation target part with the interpolation value, and generate the learning data in which the restored data is approximated to the original data, based on a first statistical index and the second statistical index regarding the original data.

In addition, in the time-series data processing device of the this disclosure, of the original data, the data corresponding to the excluding condition may be data equal to or lower than a lower limit threshold set as a lower limit value and equal to or higher than an upper limit threshold set as an upper limit value,
the data corresponding to the interpolation condition may be data in which data before and after the missing value in a time-series direction of the original data is data within a predetermined range including the lower limit threshold or a predetermined range including the upper limit threshold, and
the interpolation value may be extracted from a random number acquired based on a normal distribution function of the restored data, of the second statistical index.

In the time-series data processing device of the this disclosure, the calculation processing may be machine learning that performs learning based on a large amount of input data, and that performs estimation or determination based on a result of the learning, and
the learning data may be the input data in the machine learning,
the original data may be data regarding a power storage device mounted on a vehicle, and
the machine learning may estimate a change over time of the power storage device.

In the present disclosure, for example, in order to efficiently store a large amount of time-series data used as input data (learning data) of machine learning in a storage unit, the predetermined compression process is performed on the time-series data (original data) to reduce the amount of data. In addition, the time-series data (saved data) saved in the storage unit is subjected to a restoration process, and the data is restored to a state in which the data can be appropriately used as the learning data.

When the original data is compressed, a first statistical index related to the original data is calculated, for example, an average, a standard deviation, and a normal distribution function. At the same time, the importance of the individual data is determined by the first condition. Data of low importance is excluded as a missing value. After reducing the missing value in this way, a compression processing is performed. Then, compressed data subjected to the compression processing is stored in the storage unit as the saved data together with the first statistical index regarding the original data. Therefore, it is possible to efficiently and effectively reduce and compress the amount of data of the original data while leaving the data with high importance, that is, while leaving the characteristics of the original data, and save the original data in the storage unit.

In contrast, when the saved data (compressed data) that is compressed and saved is restored, the first statistical index obtained from the original data and the second statistical index obtained from the restored data are used. The learning data approximating the original data is generated. Specifically, a missing value (interpolation target portion) in the saved data is interpolated with an interpolation value so that the shape of the normal distribution of the original data and the shape of the normal distribution of the learning data to be restored are approximated. That is, the missing value is interpolated approximately. Here, “interpolation” is a process of calculating an approximate value for compensating for the missing value, and is, for example, an arithmetic process similar to a mathematical “linear interpolation” method. Thus, in describing the present disclosure, words such as “interpolation” and “interpolate” are used instead of “complement” and “supplement”.

Thus, according to the present disclosure, it is possible to efficiently reduce the amount of data while keeping important information, in consideration of the necessity and importance of each piece of data in the large amount of time-series data. Therefore, a large amount of time-series data can be appropriately saved without straining the storage capacity of the storage unit. Then, the compressed and saved time-series data can be well approximated to the original data and be restored, and can be appropriately used as the learning data.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing an example of a configuration and a control system of a vehicle to which a processing method and a time-series data processing method of the present disclosure are applied;

FIG. 2 is a block diagram for explaining an in-vehicle control unit and an external server in the time-series data processing apparatus of the present disclosure, and is a block diagram showing an example in which a data processing unit that executes data compression processing and restoration processing is provided in the server;

FIG. 3A is a diagram showing a series of flow of control executed by a time-series data processing method and processing device of the present disclosure, and showing an image of a process of acquiring original data of time-series data;

FIG. 3B is a diagram showing a series of flow of control executed by a time-series data processing method and a processing apparatus, wherein a first statistical index (mean, standard deviation, normal distribution function) is calculated from the quantized original data, and the original data is compressed to obtain compressed data;

FIG. 3C is a diagram showing a series of flow of control executed by a time-series data processing method and a processing apparatus according to an embodiment of the present disclosure, and showing an image of a step of storing compressed time-series data (storage data) in a storage unit;

FIG. 3D is a diagram showing a series of flows of control executed by the time-series data processing method and processing device of the present disclosure, the second statistical index (mean, standard deviation, normal distribution function) from the time-series data restored processing (restored data), and the restored data is approximated to the original data to generate the data for study It is a diagram showing an image of a process;

FIG. 4 is a block diagram for explaining an in-vehicle control unit and an external server in the time-series data processing apparatus of the present disclosure, and is a block diagram showing an example in which a data processing unit that executes data compression processing is provided in an in-vehicle control unit;

FIG. 5 is a diagram for describing an example of control executed by the time-series data processing method and processing device of according to the present disclosure, and is a flowchart showing control contents when the data compression processing is executed;

FIG. 6 is a flowchart for explaining an example of control executed by the time-series data processing method and the processing apparatus according to the present disclosure, and is a flowchart showing control contents when the data restoration processing is executed.

### DETAILED DESCRIPTION OF EMBODIMENTS

An embodiment of the present disclosure will be described with reference to the drawings. It should be noted that the embodiments shown below are merely examples of cases where the present disclosure is embodied, and do not limit the present disclosure.

The time-series data processing method and the processing device according to the embodiment of the present disclosure perform a predetermined compressing process on a large amount of time-series data (original data) used as input data of machine learning using a AI or data for learning, and reduce and store the amount of data. Then, a restoration process is performed on the stored time-series data (storage data), and the data is restored to a state that can be appropriately used as the learning data. As an example, the time-series data processing apparatus according to the embodiment of the present disclosure performs compression processing and restoration processing on time-series data (original data) used in a case where a state (deterioration state) of a power storage device mounted on a vehicle with time is estimated by machine learning with an existing general vehicle as a control target. Therefore, the time-series data processing apparatus according to the embodiment of the present disclosure includes a control unit mounted on the vehicle and a server installed outside the vehicle.

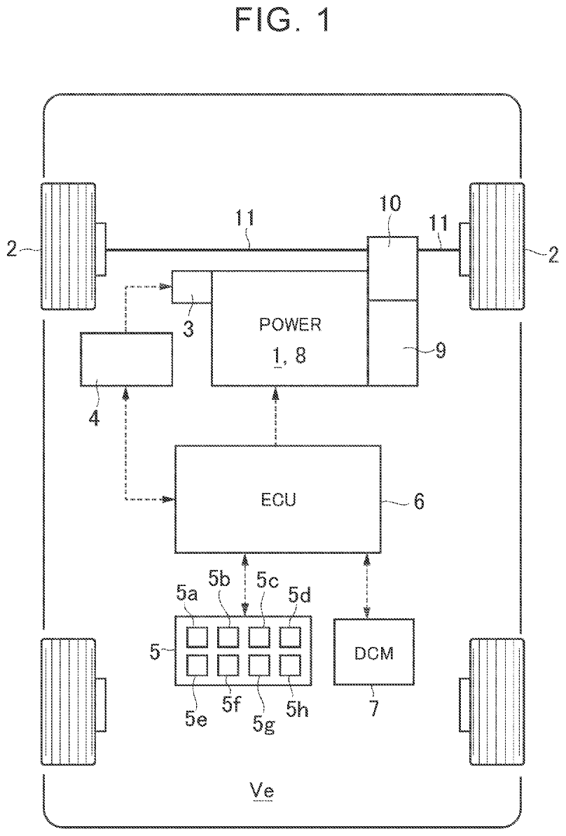

FIG. 1 shows an example of a vehicle equipped with a control unit as a constituent element of a processing device for time-series data according to an embodiment of the present disclosure. The vehicle Ve shown in FIG. 1 mainly includes a driving force source (POWER) 1, driving wheels 2, a starter motor 3, a battery 4, a detecting unit 5, a control unit (ECU) 6, and a communication module (DCM) 7.

The driving force source 1 is a power source for outputting a driving torque for driving the vehicle Ve. The driving force source 1 is, for example, an internal combustion engine such as a gasoline engine or a diesel engine, and is configured such that an operation state such as adjustment of an output and start and stop is electrically controlled. In the case of a gasoline engine, an opening degree of a throttle valve, a supply amount or an injection amount of fuel, an execution and a stop of ignition, an ignition timing, and the like are electrically controlled. Alternatively, in the case of a diesel engine, an injection quantity of fuel, an injection timing of fuel, an opening degree of a throttle valve (in a EGR system), and the like are electrically controlled. In the example illustrated in FIG. 1, an engine 8 including a starter motor 3, which will be described later, is mounted as the driving force source 1.

The driving force source 1 may be, for example, a permanent magnet synchronous motor or an electric motor such as an induction motor. The electric motor in this case may be, for example, a so-called motor generator having a function as a prime mover that is driven by being supplied with electric power to output torque and a function as a generator that generates electricity by being driven by receiving torque from the outside. In the case of a motor-generator, the number of revolutions, torque, switching between a function as a prime mover and a function as a generator, and the like are electrically controlled. Further, the driving force source 1 may be a so-called hybrid driving unit equipped with both an engine 8 and an electric motor (motor generator).

The driving wheels 2 generate the driving force of the vehicle Ve by transmitting the driving torque outputted from the driving force source 1. In the embodiment shown in FIG. 1, the driving wheels 2 are connected to a driving force source 1 via a transmission 9, a differential gear 10 and a drive shaft 11. The vehicle Ve according to the embodiment of the present disclosure may be a front wheel drive vehicle that transmits a drive torque to the front wheels and generates a drive force by the front wheels, as in the embodiment shown in FIG. 1. Alternatively, the vehicle Ve may be a rear wheel drive vehicle that transmits a drive torque to the rear wheels via, for example, a propeller shaft (not shown), and generates a drive force by the rear wheels. Alternatively, the vehicle Ve may be a four-wheel drive vehicle in which a transfer mechanism (not shown) is provided to transmit a driving torque to both the front wheel and the rear wheel, and a driving force is generated by both the front wheel and the rear wheel.

When the engine 8 is mounted as the driving force source 1 of the vehicle Ve as described above, the starter motor 3 is provided in the engine 8 and drives a crankshaft (not shown) when the engine 8 is started. The starter motor 3 operates when electric power is supplied from a battery 4 to be described later. Instead of the starter motor 3, an alternator (not shown) may function as a starter of the engine 8. Alternatively, a motor (not shown) that combines the function of a starter and the function of an alternator may be used.

The battery 4 corresponds to a “power storage device” in the embodiment of the present disclosure, and supplies electric power to the starter motor 3. In the embodiment illustrated in FIG. 1, the battery 4 is a so-called auxiliary battery, and supplies electric power to, for example, an illumination lamp of a vehicle Ve, an in-vehicle device (not illustrated) such as an air conditioner, and the like. Note that the “power storage device” in the embodiment of the present disclosure may be, for example, a main battery or a driving battery (not shown) in a hybrid electric vehicle or a battery electric vehicle.

The detecting unit 5 is a device or a device for acquiring various types of data and information required for controlling the vehicle Ve, and includes, for example, a power supply unit, a microcomputer, a sensor, an input/output interface, and the like. In particular, the detecting unit 5 according to the embodiment of the present disclosure includes a battery voltage sensor 5a that detects the voltage of the battery 4 as “power storage device”, i.e., information that is highly affected or related to the deterioration of the battery 4 when the deterioration state of the battery 4 is estimated. Further, the detecting unit 5 includes a travel distance sensor 5b that detects the travel distance of the vehicle Ve, an outside air temperature sensor 5c that detects the outside air temperature, a battery temperature sensor 5d that detects the temperature of the battery 4, a battery resistance sensor 5e that detects the internal resistance of the battery 4, and a counter 5f that measures the number of times the engine 8 is started, as information that indirectly or in combination affects the deterioration of the battery 4 even though the degree of influence or relevance to the deterioration of the battery 4 is lower than the voltage of the battery 4. In addition, the detecting unit 5 includes, for example, a vehicle speed sensor (or a wheel speed sensor) 5g that detects a vehicle speed, a rotation speed sensor 5h that detects a rotation speed of the engine 8, and the like. Further, the detecting unit 5 may include, for example, a Global Positioning System [GPS receiver (not shown) for acquiring position information of the vehicle Ve, an in-vehicle camera (not shown) for acquiring imaging information regarding an external condition of the vehicle Ve, and the like. The detecting unit 5 is electrically connected to a control unit 6, which will be described later, and outputs, as detection data, an electric signal corresponding to a detection value or a calculated value or position information of various sensors, devices, and the like as described above to the control unit 6.

The control unit 6 is, for example, an electronic control unit mainly composed of a microcomputer, and comprehensively controls Ve of vehicles. Various types of data detected or measured by the detecting unit 5 are input to the control unit 6. For this purpose, the control unit 6 has a data-acquisition unit 6a, which will be described later. Then, the control unit 6 transmits various types of data inputted to the data acquiring unit 6a to an external server 101 to be described later via a communication module 7 to be described later. At the same time, the control unit 6 performs an operation using various input data, data stored in advance, calculation formulas, and the like. The control unit 6 is configured to output the calculation result as a control command signal and control the operation and the like of each unit of the vehicle Ve. In FIG. 1, one control unit 6 is provided in one vehicle Ve, but a plurality of control units 6 may be provided for each device or device to be controlled or for each control content.

The communication module 7 transmits and receives data between the control unit 6 of the vehicle Ve and a server 101 provided outside the vehicle Ve to be described later. The communication module 7, for example, is equipped with a radio dedicated communication system (not shown) called Data Communication Module [DCM in the vehicle Ve, and transmits and receives various types of data between the control unit 6 and the server 101 using a dedicated communication line. In the embodiment of the present disclosure, data may be transmitted and received using a general-purpose communication device (not shown) using a general mobile communication line. Alternatively, for example, data may be transmitted and received by using a wired communication device installed in a dealer of a vehicle Ve, a maintenance shop, or the like.

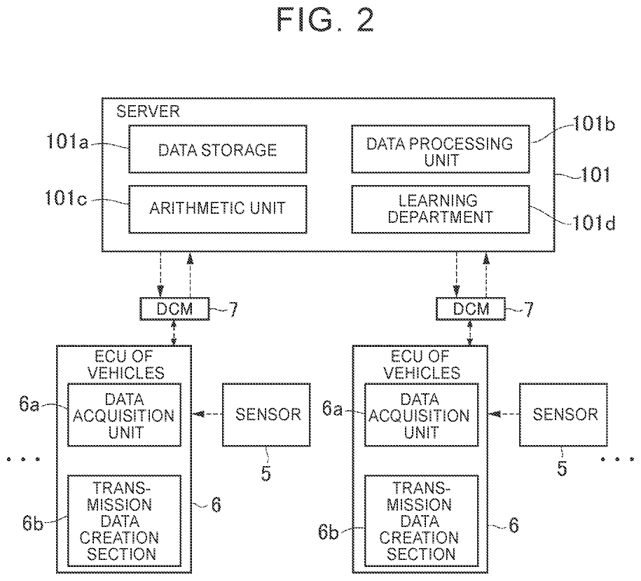

In the time-series data processing device according to the embodiment of the present disclosure, the control unit 6 transmits and receives data to and from the server 101 provided outside the vehicle Ve, and performs machine learning in cooperation with the server 101, as will be described later. For example, the deterioration state of the battery 4 as described above is estimated by machine learning using a neural network. At the same time, a compression process of reducing the amount of data and a restoration process of restoring the compressed data to a form of supplying the compressed data to the machine learning are executed on the data used for the machine learning. To this end, as illustrated in FIG. 2, the time-series data processing unit according to the embodiment of the present disclosure includes the above-described in-vehicle control unit 6 and a server 101 installed outside the vehicle Ve.

Specifically, the control unit (ECU) 6 of the vehicle Ve includes the above-described data acquiring unit 6a and the transmitting data creating unit 6b.

The data acquiring unit 6a acquires predetermined data required for generating learning data for machine-learning for each Ve of vehicles. Vehicle information for generating learning data for machine learning is acquired from various data detected by the detecting unit 5 as necessary. The vehicle information for generating the learning data for machine learning is, in other words, original data of the time-series data in the embodiment of the present disclosure. In the embodiment of the present disclosure, the time-series data is data that changes continuously in time. The original data of the time-series data is, for example, data (analog data) detected by the detecting unit 5 as it is, as shown in 3A. In 3A shown in the figures, the data (voltage/internal resistance/temperature) for the battery 4 of the vehicle Ve are shown.

The transmitting data creating unit 6b processes the various data acquired by the data acquiring unit 6a as the original data of the time-series data used in the machine learning into data for transmission adapted to the communication module 7, and transmits the data to the server 101 via the communication module 7.

In FIG. 2, the two control units 6 each transmit and receive data to and from the server 101. That is, FIG. 2 shows the control unit 6 mounted on each of the two vehicles Ve and one server 101 set externally. The time-series data processing device according to the embodiment of the present disclosure performs machine-learning using various types of data collected from the vehicle Ve. In order to improve the learning accuracy of the machine learning, it is desirable to collect as many data as possible acquired over a wide range as possible. Therefore, the time-series data-processing device according to the embodiment is not limited to Ve of two vehicles as shown in FIG. 2. A large number of data are collected from the control units 6 respectively mounted on a large number of vehicle Ve.

On the other hand, the server 101 installed outside the vehicle Ve includes, for example, a data storage unit 101a, a data processing unit 101b, an calculation unit 101c, and a learning unit 101d.

The data storage unit 101a corresponds to a “storage unit” in the embodiment of the present disclosure. Various data and information received from the control unit 6 of the vehicle Ve and various data and information calculated by the server 101 are stored in a storage device (not shown) or a storage medium (not shown) as a database related to the vehicle information. In addition, time-series data (original data) which is compressed by a data processing unit 101b to be described later and whose data volume is reduced is stored in a storage device or a storage medium.

The data processing unit 101b is equivalent to the “compression processing unit” and the “restoration processing unit” in the embodiment of the present disclosure, and executes compression processing for reducing the data amounts of a large number of time-series data that continuously change in time. Further, the restoration processing is executed on the data in which the data amount is reduced by the compression processing.

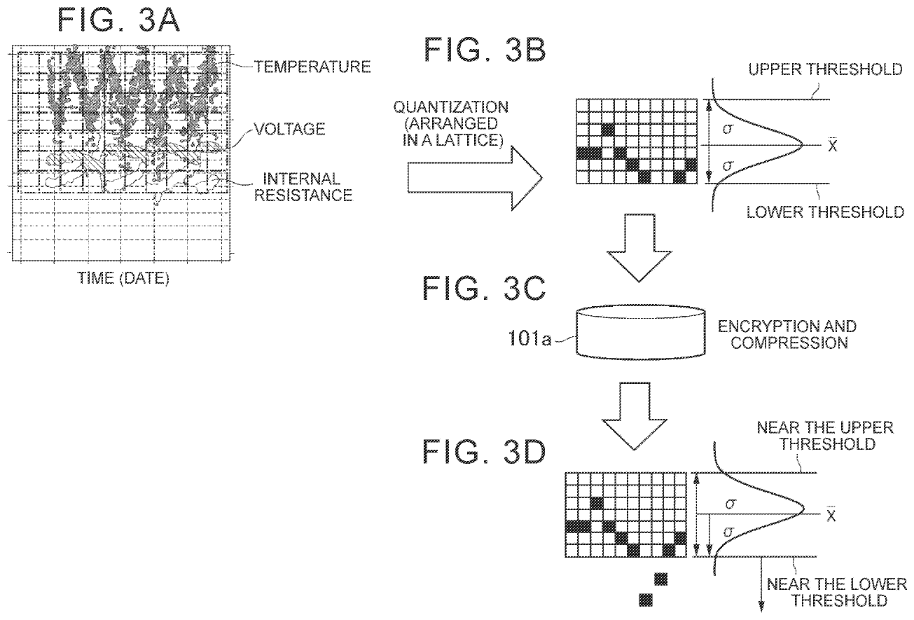

As the compression processing executed by the “compression processing unit” in the data processing unit 101b, as shown in the FIG. 3B, first, the original data of the time-series data stored in the data storage unit 101a is quantized (or discretized), and a first statistical index related to the original data is calculated. For example, at least an average, a standard deviation, and a normal distribution function of the original data are calculated.

In addition, data corresponding to the exclusion condition is excluded from the original data as a missing value (thinning out). The exclusion condition in this case corresponds to the “first condition” in the embodiment of the present disclosure, and is, for example, a threshold value for determining data having a low importance for a predetermined arithmetic processing, as in the above-described machine learning. For example, the lower limit threshold is set as the lower limit value and the upper limit threshold is set as the upper limit value with respect to the original data. Data that is equal to or lower than the lower limit threshold and equal to or higher than the upper limit threshold becomes data corresponding to the exclusion condition (first condition), and is excluded as a missing value.

In addition, compressed data in which the amount of data is reduced is generated by performing predetermined data compression processing on the original data excluding the above-described missing values. In this case, for example, an existing data compression method such as encryption or binarization is applied to the predetermined data compression processing.

Then, as shown in the FIG. 3C, the first statistical index and the compressed data are stored in the “storage unit”, that is, the data storage unit 101a as the data for storage.

On the other hand, as the restoration processing to be executed by the “restoration processing unit” in the data processing unit 101b, the storage data processed by the “compression processing unit” and stored in the data storage unit 101a is restored to data (learning data) in a form usable in a predetermined arithmetic processing as in the above-described machine learning. Specifically, first, the data for storage is read from the data storage unit 101a. Restoration data obtained by performing predetermined processing for restoring the storage data is generated as the storage data. The predetermined process in this case is a data restoration process corresponding to the above-described data compression process. In this processing, existing methods of data restoration, such as a combination for encryption and a so-called decompression process for data compression, are applied.

In addition, as shown in 3D, a second statistical index for the reconstructed data is calculated. At the same time, a position corresponding to the data corresponding to the predetermined interpolation condition is specified as the interpolation target position from among the missing positions of the restored data including the trace excluding the missing value. The interpolation condition in this case corresponds to the “second condition” in the embodiment of the present disclosure. For example, the data before and after the missing value in the time-series direction of the original data is in the vicinity of the original data, that is, in a predetermined range including the lower limit threshold of the original data, or in a predetermined range including the upper limit threshold of the original data. The position of the missing portion corresponding to the vicinity of the original data is identified as the interpolation target portion.

Then, an interpolation value to be applied to the interpolation target location is calculated on the basis of the first statistical index related to the original data and the second statistical index related to the restoration data, and the interpolation target location is interpolated with the interpolation value to generate learning data in which the restoration data is approximated to the original data.

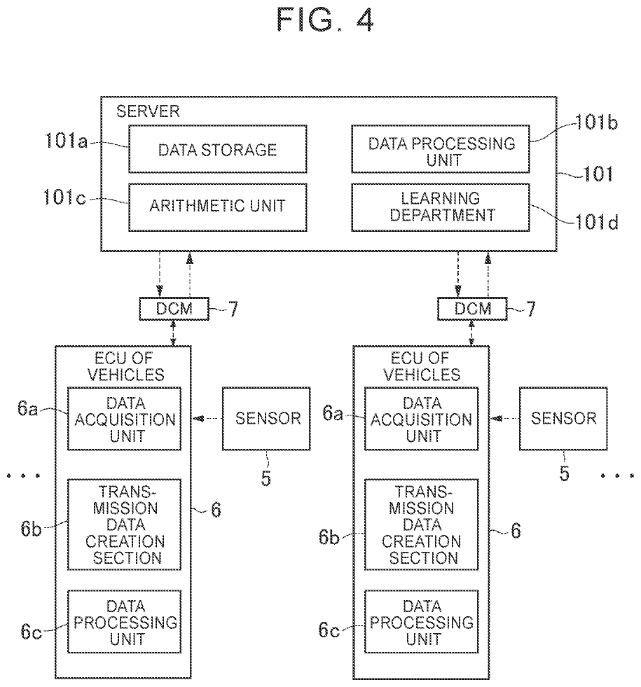

The processing device of the time-series data in the embodiment of the present disclosure, as shown in FIG. 4, the control unit 6 of the vehicle Ve may be provided with a data processing unit 6c. In this case, the compression process of calculating the first statistical index and generating the compressed data as described above may be executed by the data processing unit 6c of the in-vehicle control unit 6. Then, the data processing unit 101b of the server 101 may execute only the restoration processing as described above. That is, the data processing unit 6c of the control unit 6 may function as a “compression processing unit” in the embodiment of the present disclosure, and the data processing unit 101b of the server 101 may function as a “restoration processing unit” in the embodiment of the present disclosure.

The calculation unit 101c performs predetermined arithmetic processing on the basis of the time-series data (training data) that is compressed by the data processing unit 101b and then restored as described above. For example, well-known predetermined arithmetic processing is executed, such as machine learning using a neural network.

The learning unit 101d performs learning based on a predetermined calculation process performed by the calculation unit 101c. For example, the deteriorated state of the battery 4 of the vehicle Ve, that is, the state of the performance of the battery 4 over time is estimated based on the above-described machine learning.

As described above, the time-series data processing method and processing device according to the embodiment of the present disclosure mainly aims to appropriately reduce and store the amount of data while taking into consideration the necessity and importance of each piece of data in a large amount of time-series data, and to use the data. To this end, the time-series data processing method and the processing apparatus according to the embodiment of the present disclosure are configured to execute the control shown in the following flowcharts.

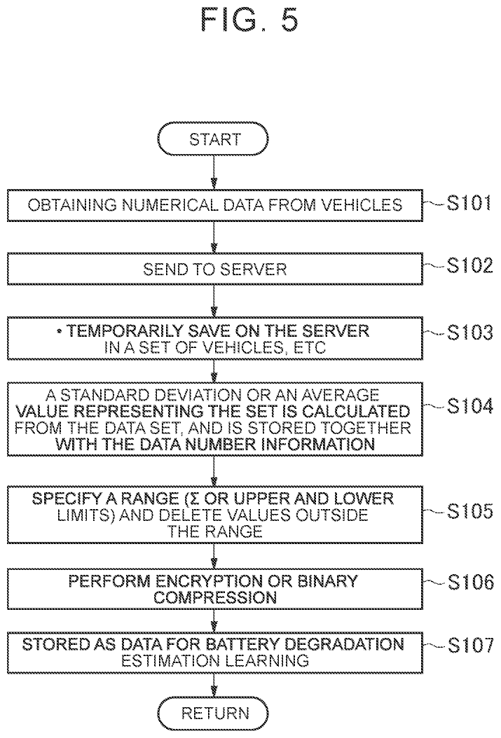

The flow chart of FIG. 5 shows a compression processing step of performing a predetermined compression process on the original data of the time-series data, and reducing the amount of data into storage data in a form that can be stored in a storage unit (data storage unit 101a), and a compression process of performing the compression process. In the flow chart shown in FIG. 5, first, in S101, various types of vehicle data including numerical data related to the battery 4 are acquired for each vehicle Ve in the control unit 6 of the vehicle Ve.

Next, in S102, the acquired various types of vehicle-information are transmitted to the server 101 by radio communication or the like. For example, the vehicle data is acquired every time an ignition switch (not shown) is turned ON in the respective vehicle Ve. As described above, the vehicle data may be transmitted from the control unit 6 of the vehicle Ve to the external server 101 by using a wired communication device or a communication facility.

Subsequently, in S103, various types of vehicle data transmitted from the respective vehicle Ve and received are stored in the server 101. For example, the received various types of vehicle information are set (set data) for each predetermined vehicle (vehicle type) for a predetermined period of time. In addition, at this time, numerical data related to various types of vehicle information is quantized and processed in the form of time-series data that continuously changes in time. Then, the data is temporarily stored in the server 101 as the original data of the time-series data.

In S104, the first statistical index (or basic statistic) in the set data is calculated from the set data of the original data temporarily stored in the server 101 as described above. Specifically, as the first statistical index, at least an average value, a standard deviation, a normal distribution function, and the like of the set data (original data) are calculated. Further, the calculated first statistical index is stored in the server 101 together with the information (data number information) of the individual data of the set data (original data). Note that the timing at which the data related to the first statistical index is stored in the server 101 is a S107 which will be described later. The data related to the first statistical index may be stored in the server 101 as data for storage together with the compressed data.

In S105, a range is specified for the set data (original data), and values outside the range are deleted. Specifically, data corresponding to the exclusion condition (first condition) is excluded as a missing value (thinned out) from the set data (original data). As described above, the exclusion condition in this case, that is, the first condition in the embodiment of the present disclosure, is a threshold set for determining data having a low importance to a predetermined arithmetic processing (machine learning). The data corresponding to the exclusion condition is data equal to or lower than the lower limit threshold set as the lower limit value and equal to or higher than the upper limit threshold set as the upper limit value among the set data (original data).

In S106, predetermined (pre-existing) data compression processes such as encryption and binarization are performed on the set data (original data) excluding the above-described missing values, and compressed data in which the amount of data is reduced is generated.

Then, in S107, the compressed data generated by the above-described S106 is stored in the server 101, for example, as data for battery-deterioration estimation learning, that is, as storage data for machine-learning. As described above, in this S107, both the compressed data and the first statistical index may be stored in the server 101 as storage data. When this S107 is executed, the routine shown in the flow chart of FIG. 5 is terminated once.

The control content in each step illustrated in the flowchart of FIG. 5 corresponds to the compression processing step of the time-series data processing method in the embodiment of the present disclosure. Specifically, the above-described S104 corresponds to a “step of calculating a first statistical index relating to original data” in the compression processing step. S105 corresponds to a step of excluding, as a missing value, data corresponding to a predetermined first condition (exclusion condition) for discriminating data having a low importance to a predetermined arithmetic processing from the original data in the compression processing step. S106 corresponds to a step of performing compression processing on original data excluding a missing value in the compression processing step, and generating compressed data in which the amount of data is reduced. S107 corresponds to the step of storing the compressed data and the first statistical index in the storage unit as the storage data in the compression processing step.

As described above, in the time-series data processing method and the processing device according to the embodiment of the present disclosure, when the original data of the time-series data is compressed by the compression processing step performed by the time-series data processing device and the compression processing performed by the time-series data processing method, for example, the first statistical index related to the original data such as an average, a standard deviation, and a normal distribution function is calculated. At the same time, the importance of the individual data is determined by the first condition (exclusion condition), and data with low importance is excluded as a mis sing value. After reducing the missing value in this way, a predetermined compression process is performed. Then, the compressed data subjected to the compression processing is stored in the storage unit as the storage data together with the first statistical index related to the original data. Therefore, the original data of the time-series data can be efficiently and effectively saved in the data storage unit 101a (storage unit) while leaving the data of higher importance, that is, while leaving the characteristics of the original data.

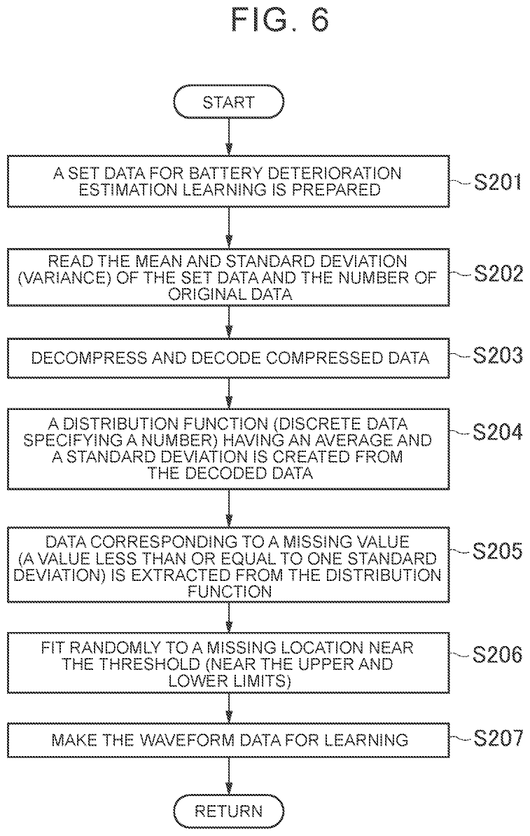

On the other hand, the flowchart of FIG. 6 shows a restoration processing of converting the data for storage into learning data in a form usable in predetermined arithmetic processing (machine learning) and a restoration process of executing the restoration process. In the flow chart shown in FIG. 6, first, in S201, for example, data for battery-deterioration estimation learning, that is, set data for storage data for machine learning, is prepared.

Then, in S202, the first statistical index (with respect to the original data) (mean, standard-deviation, etc.) of the set data and the compressed data corresponding to the number of the original data are read out.

In S203, a data restoration process is performed on the read compressed data. For example, a so-called decompression process is performed on the encrypted data and the compressed data to generate restored data.

In S204, a second statistical index for the restored data is calculated from the restored (decoded) data. For example, the average of the reconstructed data, the standard deviation, and a normal distribution function (discrete data specifying the number) having the average and the standard deviation are calculated.

In S205, data corresponding to the missing value (a value equal to or less than the “mean-standard deviation”) is extracted based on the calculated normal distribution function. Specifically, a position corresponding to the data corresponding to the interpolation condition (second condition) is specified from the missing portion of the original data as the interpolation target portion, and an interpolation value to be applied to the interpolation target portion is calculated based on the second statistical index related to the restored data. The interpolation value in this case is extracted from the random number obtained based on the normal distribution function of the restored data among the calculated second statistical indices.

In S206, the interpolated values extracted as described above are applied to the missing portions. That is, the interpolation target portion of the missing portion is interpolated by the interpolation value. That is, the interpolation target portion (missing value) is approximately interpolated by the interpolation value.

Then, in S207, the interpolation target portion is interpolated with the interpolation value as described above, so that the training data in which the restored data is approximated to the original data is generated. That is, the learning data is generated such that the shape of the normal distribution in the first statistical index with respect to the original data is approximated to the shape of the normal distribution in the second statistical index with respect to the restored data. When this S207 is executed, the routine shown in the flow chart of FIG. 6 is terminated once.

The control content in each step illustrated in the flowchart of FIG. 6 corresponds to the restoration processing step of the time-series data processing method in the embodiment of the present disclosure. Specifically, the above-described S202 corresponds to the “step of reading the storage data (the compressed data and the first statistical index) from the storage unit” in the restoration processing step. S203 corresponds to a step of generating restored data in which predetermined processing for restoring the data for storage is performed on the data for storage in the restoration processing step. S204 corresponds to a “step of calculating a second statistical index relating to the restoration processing step”. S205 corresponds to a step of specifying a position corresponding to data corresponding to a predetermined second condition (interpolation condition) from among the missing portions of the restored data including a trace excluding the missing value in the restoration processing step as an interpolation target portion. S206 and S207 correspond to a step of calculating an interpolation value to be applied to the interpolation target location on the basis of the first statistical index and the second statistical index in the restoration processing step, interpolating the interpolation target location of the restoration data with the calculated interpolation value, and generating training data in which the restoration data is approximated to the original data.

As described above, in the time-series data processing method and processing device according to the embodiment of the present disclosure, the first statistical index obtained from the original data and the second statistical index obtained from the restored data are used in the restoration processing by the time-series data processing device and the restoration processing step in the time-series data processing method, and the learning data approximated to the original data is generated. Specifically, when the storage data (compressed data) stored in the compressed state is restored, the missing value in the storage data is interpolated so that the shape of the normal distribution of the original data and the shape of the normal distribution of the learning data to be restored are approximated. Therefore, it is possible to restore the learning data in which the characteristics of the original data subjected to the compression processing are appropriately reproduced.

As described above, according to the time-series data processing method and processing device according to the embodiment of the present disclosure, it is possible to efficiently reduce the amount of data while keeping important information in consideration of the necessity and importance of each piece of data in a large amount of time-series data. Therefore, a large amount of time-series data can be appropriately stored without tightening the storage capacity of the data storage unit 101a (storage unit). Then, the compressed and stored time-series data can be restored by making it closely approximate to the original data, and can be appropriately used, for example, as learning data for machine learning.

What is claimed is:

1. A time-series data processing method that reduces a data amount of a large amount of time-series data that varies continuously in time, the time-series data processing method comprising:
a compression processing step that performs predetermined compression processing on original data of the time-series data that is quantized, and that reduces the data amount to make saved data in a form that is able be saved in a predetermined storage unit; and
a restoration processing step that performs restoration processing on the saved data, and that makes the saved data into study data in a form usable by predetermined calculation processing,
wherein the compression processing step includes,
a step of calculating a first statistical index regarding the original data,
a step of excluding, from the original data, data corresponding to a predetermined first condition as a missing value,
a step of performing the compression processing on the original data from which the missing value is excluded, and generating compressed data in which the data amount is reduced, and
a step of storing the compressed data and the first statistical index as the saved data in the storage unit, and
wherein the restoration processing step includes:
a step of reading the saved data from the storage unit;
a step of generating restored data in which predetermined processing of restoring the saved data is performed on the saved data;
a step of calculating a second statistical index regarding the restored data;
a step of specifying a position corresponding to data applicable to a predetermined second condition as an interpolation target part, from a missing part of the restored data containing a trace in which the missing value is excluded, and
a step of calculating an interpolation value applied to the interpolation target part, compensating the interpolation target part with the interpolation value, and generating learning data in which the restored data is approximated to the original data, based on the first statistical index and the second statistical index.

2. The time-series data processing method according to claim 1,
wherein of the original data, the data corresponding to the first condition is data equal to or lower than a lower limit threshold set as a lower limit value and equal to or higher than an upper limit threshold set as an upper limit value,
wherein the data corresponding to the second condition is data in which data before and after the missing value in a time-series direction of the original data is data within a predetermined range including the lower limit threshold or a predetermined range including the upper limit threshold, and
wherein the interpolation value is extracted from a random number acquired based on a normal distribution function of the restored data.

3. The time-series data processing method according to claim 2,
wherein the calculation processing is machine learning that performs learning based on a large amount of input data, and that performs estimation or determination based on a result of the learning, and
wherein the learning data is the input data in the machine learning.

4. The time-series data processing method according to claim 3,
wherein the original data is data regarding a power storage device mounted on a vehicle, and
wherein the machine learning estimates a change over time of the power storage device.

5. A time-series data processing device that reduces a data amount of a large amount of time-series data that varies continuously in time, the time-series data processing method comprising
a compression processing unit that performs predetermined compression processing on original data of the time-series data that is quantized, and that reduces the data amount to make the original data into saved data in a form that is able be saved in a predetermined storage device or a storage medium,
wherein the compression processing unit:
calculates a first statistical index regarding the original data;
excludes, from the original data, data corresponding to a predetermined excluding condition as a missing value;
performs the compression processing on the original data from which the missing value is excluded, and generates compressed data in which the data amount is reduced; and
saves the compressed data and the first statistical index as the saved data in the storage device and the storage medium.

6. The time-series data processing device according to claim 5,
wherein of the original data, the data corresponding to the excluding condition is data equal to or lower than a lower limit threshold set as a lower limit value and equal to or higher than an upper limit threshold set as an upper limit value.

7. A time-series data processing device that reduces a data amount of a large amount of time-series data that varies continuously in time, the time-series data processing method comprising
a restoring processing unit that performs restoring processing on saved data saved in a predetermined storage device or a storage medium and that makes the saved data into learning data in a form usable by predetermined calculation processing, the saved data being data in which predetermined compression processing is performed on original data from which data corresponding to a predetermined excluding condition is excluded as a missing value and the data amount is reduced, from the original data of the time-series data that is quantized,
wherein the restoration processing unit:
reads the saved data from the storage device or the storage medium;
generates restored data in which predetermined processing of restoring the saved data is performed on the saved data;
calculates a second statistical index regarding the restored data;
specifies a position corresponding to data applicable to a predetermined interpolation condition as an interpolation target part, from a missing part of the restored data containing a trace in which the missing value is excluded; and
calculates an interpolation value applied to the interpolation target part, compensates the interpolation target part with the interpolation value, and generates the learning data in which the restored data is approximated to the original data, based on a first statistical index and the second statistical index regarding the original data.

8. The time-series data processing device according to claim 7,
wherein of the original data, the data corresponding to the excluding condition is data equal to or lower than a lower limit threshold set as a lower limit value and equal to or higher than an upper limit threshold set as an upper limit value,
wherein the data corresponding to the interpolation condition is data in which data before and after the missing value in a time-series direction of the original data is data within a predetermined range including the lower limit threshold or a predetermined range including the upper limit threshold, and
wherein the interpolation value is extracted from a random number acquired based on a normal distribution function of the restored data.

9. The time-series data processing device according to claim 8,
wherein the calculation processing is machine learning that performs learning based on a large amount of input data, and that performs estimation or determination based on a result of the learning, and
wherein the learning data is the input data in the machine learning,
wherein the original data is data regarding a power storage device mounted on a vehicle, and
wherein the machine learning estimates a change over time of the power storage device.
